(19) United States
(12) Patent Application Publication
(10) Pub. No.: US 2026/0255778 A1
(43) Pub. Date: Aug. 27, 2026

(54) ZINC OXIDE NANOCRYSTAL AND PREPARATION METHOD THEREFOR, AND LIGHT EMITTING DEVICE

(71) Applicant: TCL Technology Group Corporation, Huizhou, Guangdong (CN)

(72) Inventors: Likuan ZHOU, Huizhou, Guangdong (CN); Yixing YANG, Huizhou, Guangdong (CN)

(73) Assignee: TCL Technology Group Corporation, Huizhou, Guangdong (CN)

(21) Appl. No.: 18/861,208

(22) PCT Filed: Dec. 28, 2022
(86) PCT No.: PCT/CN2022/143058

§ 371 Date: Oct. 28, 2024

(30) Foreign Application Priority Data
Jul. 14, 2022 (CN) 202210827219.3

(51) Int. Cl. H10K 50/115; H10K 71/00

(52) U.S. Cl. CPC H10K 50/115; H10K 71/811

(57) ABSTRACT

Disclosed are a zinc oxide nanocrystal and a preparation method therefor, and a light emitting device. The preparation method comprises: mixing a zinc salt, a doping metal salt, and a first solvent to obtain a first mixed solution; injecting an alkali liquor into the first mixed solution to obtain a second mixed solution; and performing pressurized reaction treatment at 0.2-5 MPa on the second mixed solution to obtain the zinc oxide nanocrystal.

The present disclosure claims priority to Chinese Patent Application No. 202210827219.3, filed in the China National Intellectual Property Administration on Jul. 14, 2022, and entitled “ZINC OXIDE NANOCRYSTAL AND PREPARATION METHOD THEREFOR, AND LIGHT EMITTING DEVICE”, which is incorporated herein by reference in its entirety.

### TECHNICAL FIELD

The present disclosure relates to a field of light emitting devices, and in particular, to a zinc oxide nanocrystal and a preparation method therefor, and a light emitting device.

### BACKGROUND

Light-emitting devices include, but are not limited to, organic light-emitting diodes (OLEDs) and quantum dot light-emitting diodes (QLEDs).

Among light-emitting devices, a device consist of an anode, a hole injection layer, a hole transport layer, a light-emitting layer, an electron transport layer, and a cathode. Among many inorganic metal oxide candidates for electron transport layers, highly crystalline zinc oxide in the form of sol-gel films or nanoparticles (NPs) has been most widely used in electron transport layers. Due to its high electron mobility and good band alignment, ZnO greatly improves device performance. In order to better meet the different requirements of electron injection performance in the structure of QLED device, ZnXO is obtained by doping metal elements in zinc oxide nanocrystals, wherein X is a doped metal element, which can adjust the energy level and the mobility of zinc oxide in an electron transport layer.

However, a doped zinc oxide synthesized by sol-gel method has a problem that a doping conversion rate of doped metal elements is not high.

### SUMMARY

Therefore, the present disclosure provides a zinc oxide nanocrystal and a preparation method therefor, and a light emitting device.

The present disclosure provides a method for preparing a zinc oxide nanocrystal, including:
mixing a zinc salt, a doped metal salt, and a first solvent to obtain a first mixed solution;
injecting an alkali solution into the first mixed solution to obtain a second mixed solution; and
performing a pressurized reaction treatment at 0.2-5 MPa on the second mixed solution to obtain the zinc oxide nanocrystal.

Alternatively, in some embodiments of the present disclosure, after the pressurized reaction treatment, the method further includes:
adding a precipitating agent to a reactant-containing solution subjected to the pressurized reaction treatment to obtain the zinc oxide nanocrystal, wherein the precipitating agent is selected from one or more of ethyl acetate, acetone, n-hexane, and n-heptane.

Alternatively, in some embodiments of the present disclosure, a volume ratio of the reactant-containing solution to the precipitating agent ranges from 2:1 to 6:1.

Alternatively, in some embodiments of the present disclosure, the step of performing a pressurized reaction treatment at 0.2-5 MPa on the second mixed solution to obtain the zinc oxide nanocrystal includes:

transferring the second mixed solution to a sealed reaction vessel which is filled with a protective gas, and performing the pressurized reaction treatment under a pressure of 0.2 to 5 MPa.

Alternatively, in some embodiments of the present disclosure, the protective gas is selected from one or more of nitrogen, argon, carbon dioxide, and oxygen.

Alternatively, in some embodiments of the present disclosure, a temperature of the pressurized reaction treatment ranges from 0° C. to 50° C., and a reaction time ranges from 30 minutes to 4 hours.

Alternatively, in some embodiments of the present disclosure, a molar amount of hydroxide ions in the alkali solution is A, a sum of a molar amount of zinc ions in the zinc salt and a molar amount of metal ions in the doped metal salt is B, and a ratio of A to B ranges from 0.5:1 to 1.5:1.

Alternatively, in some embodiments of the present disclosure, the zinc salt is selected from one or more of zinc acetate, zinc nitrate, zinc sulfate, and zinc chloride.

Alternatively, in some embodiments of the present disclosure, the doped metal salt is selected from one or more of a magnesium salt, an aluminum salt, a cadmium salt, a lithium salt, and a gallium salt; wherein the magnesium salt is selected from one or more of magnesium acetate, magnesium nitrate, magnesium sulfate, and magnesium chloride, the lithium salt is selected from one or more of lithium acetate, lithium nitrate, lithium sulfate, and lithium chloride, the gallium salt is selected from one or more of gallium acetate, gallium nitrate, gallium sulfate, and gallium chloride, the aluminum salt is selected from one or more of aluminum acetate, aluminum nitrate, aluminum sulfate, and aluminum chloride, and the cadmium salt is selected from one or more of cadmium acetate, cadmium nitrate, cadmium sulfate, and cadmium chloride.

Alternatively, in some embodiments of the present disclosure, an alkali in the alkali solution is selected from one or more of potassium hydroxide, sodium hydroxide, lithium hydroxide, TMAH, ethanolamine, and ethylenediamine.

Alternatively, in some embodiments of the present disclosure, the first solvent, a second solvent for dissolving the alkali solution, and a third solvent for dissolving a metal-doped zinc oxide nanocrystal are independently selected from one or more of water, methanol, ethanol, propanol, butanol, ethylene glycol, 2-Methoxyethanol, and dimethyl sulfoxide.

Alternatively, in some embodiments of the present disclosure, a doped metal element in the zinc oxide nanocrystal is selected from one or more of magnesium, aluminum, cadmium, lithium, and gallium.

Alternatively, in some embodiments of the present disclosure, the zinc salt is zinc acetate;
the doped metal salt is cadmium acetate or magnesium acetate;
the alkali in the alkali solution is TMAH or lithium hydroxide;
the first solvent is dimethyl sulfoxide.

Alternatively, in some embodiments of the present disclosure, the pressure ranges from 0.8 MPa to 4 MPa.

Alternatively, in some embodiments of the present disclosure, the zinc salt is zinc acetate, the doped metal salt is magnesium acetate, the alkali in the alkali solution is TMAH, the first solvent is dimethyl sulfoxide and the pressure is 4 MPa.

Correspondingly, an embodiment of the present disclosure further provides a zinc oxide nanocrystal obtained by the method as described above.

Alternatively, in some embodiments of the present disclosure, an average particle size of the zinc oxide nanocrystal ranges from 3 to 20 nm.

Correspondingly, an embodiment of the present disclosure further provides a light-emitting device including:
a cathode, an anode, a light-emitting layer disposed between the cathode and the anode, and an electron transport layer disposed between the cathode and the light-emitting layer, wherein a material of the electron transport layer is a zinc oxide nanocrystal prepared by the method as described above, or a zinc oxide nanocrystal as described above.

Alternatively, in some embodiments of the present disclosure, the anode is selected from one or more of indium tin oxide, fluorine-doped tin oxide, indium zinc oxide, graphene and carbon nanotube; and/or
the light-emitting layer is a quantum dot light-emitting layer, and the quantum dot light-emitting layer is a red quantum dot light-emitting layer, a green quantum dot light-emitting layer, a blue quantum dot light-emitting layer or a multi-component mixed quantum dot light-emitting layer; a material of the quantum dot light-emitting layer includes at least one of nanocrystals of a Group II-VI semiconductor, nanocrystals of a Group III-V semiconductor, a Group II-V compound, a Group III-VI compound, a Group IV-VI compound, a Group I-III-VI compound, a Group II-IV-VI compound, and a Group IV elemental substance; and/or
the cathode is selected from one or more of Al, Ca, Ba, and Ag.

Alternatively, in some embodiments of the present disclosure, the light-emitting device further includes:
a hole injection layer and a hole transport layer, wherein the hole injection layer and the hole transport layer are disposed between the light-emitting layer and the anode, the hole injection layer is disposed close to the anode, the hole transport layer is disposed close to the light-emitting layer, a material of the hole injection layer is selected from one or more of PEDOT:PSS, nickel oxide, molybdenum oxide, tungsten oxide, vanadium oxide, molybdenum sulfide, tungsten sulfide, and copper oxide; and, a material of the hole transport layer is selected from one or more of PVK, Poly-TPD, CBP, TCTA, and TFB.

### BRIEF DESCRIPTION OF THE DRAWINGS

In order to illustrate the technical solutions of the present disclosure clearly, the following will briefly describe the accompanying drawings involved in the description of embodiments. It will be apparent that the drawings in the following description are merely some of the embodiments of the present disclosure, and other drawings may be obtained by those skilled in the art without involving any inventive effort based on these drawings.

FIG. 1 is a flow chart of a method for preparing a zinc oxide nanocrystal according to an embodiment of the present disclosure.

FIG. 2 is a schematic diagram of an upright light-emitting device according to an embodiment of the present disclosure.

FIG. 3 is a schematic diagram of an inverted light-emitting device according to another embodiment of the present disclosure.

FIG. 4 is a flow chart of a method for preparing a zinc oxide nanocrystal according to another embodiment of the present disclosure.

FIG. 5 is a flow chart of a method for preparing a zinc oxide nanocrystal according to a third embodiment of the present disclosure.

### DESCRIPTION OF REFERENCE NUMBERS

substrate: 10; anode: 20; hole injection layer: 30; hole transport layer: 40; light-emitting layer: 50; electron transport layer: 60; cathode: 70.

### DETAILED DESCRIPTION OF THE PREFERRED EMBODIMENTS

The technical solutions in the present disclosure will be fully and clearly described with reference to the accompanying drawings. It is apparent that the described embodiments are only a part of the embodiments of the present disclosure, rather than all of the embodiments. Based on the embodiments in the present disclosure, all other embodiments obtained by a person skilled in the art without involving any inventive effort fall within the scope of the present disclosure.

It should be noted that the order of description of the following embodiments is not intended as a limitation of the preferred order of the embodiments. In addition, in the description of the present disclosure, the term “includes” means “includes but is not limited to”.

Various embodiments of the present disclosure may exist in the form of a range. It should be understood that the description in range format is merely for convenience and brevity, and should not be construed as a rigid restrictions on the scope of the present disclosure. Therefore, it should be considered that the range description has specifically disclosed all possible sub-ranges as well as a single value within the range. For example, it should be considered that the range description from 1 to 6 has specifically disclosed sub-ranges, such as from 1 to 3, from 1 to 4, from 1 to 5, from 2 to 4, from 2 to 6, from 3 to 6, and the like, and single numbers within the ranges, such as 1, 2, 3, 4, 5, and 6, which apply regardless of the range. In addition, whenever a numeric range is indicated herein, it includes any referenced number (fraction or integer) within the referenced range.

In the present disclosure, “one or more” means one or more, and “more” means two or more. “One or more”, “at least one of the following” or similar expressions refer to any combination of these items, including any combination of single items (items) or complex items (items). For example, “at least one of a, b, or c”, or “at least one of a, b, and c” may all represent a, b, c, a-b (representing a and b), a-c, b-c, or a-b-c, wherein a, b, and c, respectively, may be single or multiple.

At present, the sol-gel method is mostly used to prepare an electron transport layer. The method mainly reacts a metal salt compound of zinc with an alkali at normal pressure, normal temperature or low temperature to generate an intermediate product Zn(OH)₂, and then obtains zinc oxide (ZnO) nanocrystals through an intermolecular polycondensation reaction. The doped metal atoms replace the positions of metal zinc atoms in zinc oxide nanocrystals, and different metal atoms produce different defect state energy levels, thus changing the energy level position and the mobility of zinc oxide nanocrystals. Because the reaction conditions are relatively mild, the doping amount of metal doping reaction is far lower than the feedstock dosage. Through ICP-AES test, it is found that the real doping ratio is lower than 50% when the amount of doped metal is high (>20%), which leads to a large difference between a band gap width of an actual doped zinc oxide nanocrystal and a theoretically calculated band gap width; moreover, even with a low feedstock dosage, the real doping ratio is lower than 80%, which also caused a large error in the judgment of the properties of zinc oxide nanocrystals. In general, the doping effect can be promoted by increasing a reaction temperature. However, in the synthesis process of zinc oxide nanocrystals, increasing the reaction temperature may accelerate the polycondensation reaction, resulting in the rapid enlargement of nanocrystalline particles, which is easy to cause the problem of agglomeration and sedimentation of large particles. At the same time, the size effect of nanocrystals leads to a smaller band gap, making nanocrystals unsuitable for device structures requiring zinc oxide nanocrystals with wide band gap.

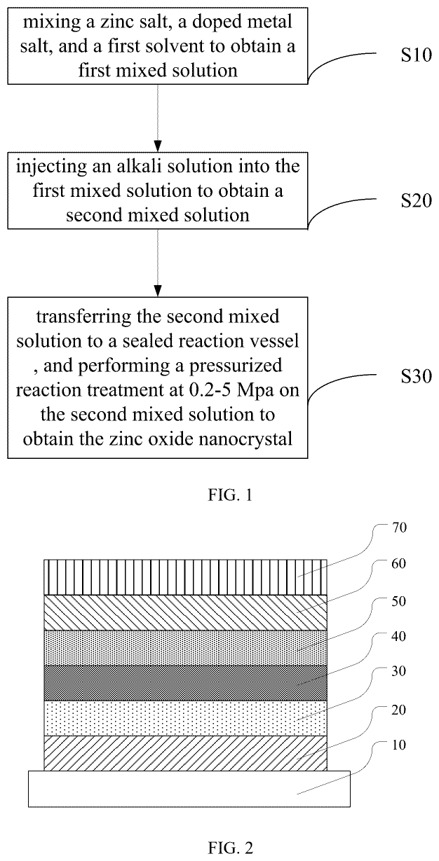

In view of this, firstly, as shown in FIG. 1, an embodiment of the present disclosure provides a method for preparing a zinc oxide nanocrystal. The method includes:
S10, mixing a zinc salt, a doped metal salt, and a first solvent to obtain a first mixed solution;
S20, injecting an alkali solution into the first mixed solution to obtain a second mixed solution; and
S30, performing a pressurized reaction treatment at 0.2-5 MPa on the second mixed solution to obtain the zinc oxide nanocrystal.

In some embodiments, as shown in FLG. 4, the step S30 may include a step S31 of performing a pressurized reaction treatment at 0.2-5 MPa on the second mixed solution, and then adding a precipitating agent to a reactant-containing solution subjected to the pressurized reaction treatment to obtain the zinc oxide nanocrystal.

In the preparation method provided by the present disclosure, the zinc oxide nanocrystals are doped under a pressure condition of 0.2 MPa to 5 Mpa, and the doped metal elements are promoted to effectively enter the zinc oxide nanocrystals by externally applied pressure, so as to improve the feeding doping conversion rate; on the other hand, the existence of pressure may further improve the crystallization performance of zinc oxide nanocrystals, make the zinc oxide nanocrystals stack more closely, and reduce the defect states on the surface of zinc oxide nanocrystals, which is conducive to eliminating the quenching of a light-emitting layer by the defect states and improving the luminous efficiency of a device. In addition, the yield of nanocrystals may also be increased.

In the process of preparing zinc oxide nanocrystals, if the applied pressure is too small, for example, when the pressure is less than 0.2 MPa, the driving effect on the doping of metal ions into zinc oxide nanocrystals is relatively weak. After testing, it is found that under the condition of high feedstock dosage (the molar ratio of doped metal to zinc ions is greater than 10%), although the conversion rate is higher than that obtained by atmospheric pressure reaction, it is still lower than 80%, and the correlation between doping amount and energy level band gap and mobility in doped zinc oxide nanocrystals cannot be truly obtained. Although in the reaction system with low feedstock dosage (the molar ratio of doped metal to zinc ions is less than 10%), the conversion rate of feedstock dosage can reach more than 90%, but there are still errors.

In the process of preparing zinc oxide nanocrystals, high pressure is generated by introducing gas from the outside world. If the applied pressure is too small, for example, when the pressure is greater than 5 MPa, the surface of zinc oxide nanocrystals will be surrounded by the atmosphere in a high-density dry atmosphere, resulting in the problem of delaying the polycondensation reaction. As a result, on the one hand, the polycondensation reaction speed of zinc oxide is reduced; on the other hand, the crystallization of zinc oxide nanocrystals is promoted under high pressure, which has a repulsive effect on doped metal ions, resulting in a certain impact on doping efficiency. In addition, when the pressure is greater than 5 Mpa, the pressure resistance of the reaction vessel is required to be higher, which will cause certain danger and is not conducive to safe operation.

Therefore, under the same doping conditions, the reaction is carried out at the pressure condition of 0.2 MPa to 5 Mpa (megapascals), which can improve the conversion rate of feedstock dosage on the basis of ensuring the safety of the operation, and can also establish the correlation with the energy level band gap and mobility by the doping amount. It may be understood that a range of the pressure in the process of preparing the zinc oxide nanocrystals may be any value in the range of 0.2 to 5 Mpa, such as 0.2 to 1 Mpa, 1 to 1.5 Mpa, 1.5 to 2 Mpa, 2 to 2.5 Mpa, 2.5 to 3 Mpa, 3 to 3.5 Mpa, 3.5 to 4 Mpa, 4 to 4.5 Mpa, 4.5 to 5 Mpa, and the like, or other values not listed in the range of 0.2 to 5 Mpa.

In some embodiments, the step S20 of injecting the alkali solution into the first mixed solution to obtain the second mixed solution specifically includes:

An alkali is dissolved in a second solvent to obtain the alkali solution, and then the alkali solution is dropwise added or injected into the first mixed solution at one time to obtain the second mixed solution.

In some embodiments, a molar amount of hydroxide ions in the alkali solution is A, a sum of a molar amount of zinc ions in the zinc salt and a molar amount of metal ions in the doped metal salt is B, and the ratio of A to B ranges from 0.5:1 to 1.5:1. Within this range, the preparation of zinc oxide nanocrystals is favorable. It may be understood that a ratio of A to B may be any value in the range of 0.5:1 to 1.5:1, such as 0.5:1 to 0.6:1, 0.6:1 to 0.7:1, 0.7:1 to 0.8:1, 0.8:1 to 0.9:1, 1:1 to 1.1:1, 1.1:1 to 1.2:1, 1.2:1 to 1.3:1, 1.3:1 to 1.4:1, 1.4:1 to 1.5:1, and the like, or other unlisted values in the range of 0.5:1 to 1.5:1.

In some embodiments, as shown in FLG. 5, the step S30 of performing the pressurized reaction treatment at 0.2-5 MPa on the second mixed solution to obtain the zinc oxide nanocrystal includes:
step S32, transferring the second mixed solution to a sealed reaction vessel which is filled with a protective gas, and performing the pressurized reaction treatment under a pressure of 0.2 to 5 MPa.

In some embodiments, a temperature of the pressurized reaction treatment ranges from 0° C. to 50° C., and a reaction time ranges from 30 minutes to 4 hours.

The reaction process in step S30 specifically refers to a doping reaction: the zinc salt reacts with the alkali to generate the intermediate product Zn(OH)₂, and then the zinc oxide nanocrystal is obtained through the intermolecular polycondensation reaction, and the doped metal atoms replace the positions of metal zinc atoms in the zinc oxide nanocrystal. Because the doping reaction is carried out under the pressure condition of 0.2-5 Mpa, the externally applied pressure promotes the doped metal element to effectively enter the zinc oxide nanocrystal, and the doping conversion rate of the feedstock dosage is improved; on the other hand, the crystallization performance of zinc oxide nanocrystals can be further improved, which is conducive to eliminating the quenching of the light-emitting layer by defect states and improving the luminous efficiency of the device.

In some embodiments, a drying gas is selected from, but not limited to, one or more of nitrogen, argon, carbon dioxide and oxygen.

In some embodiments, the reaction time is 30 minutes to 4 hours. Within this time frame, a sufficient reaction is favored. It may be understood that the reaction time is any value in the range of 30 min to 4 h, for example, 30 min to 1 h, 1 h to 2 h, 2 h to 3 h, 3 h to 4 h, and the like, or other values not listed in the range.

In some embodiments, the step of adding a precipitating agent to a reactant-containing solution subjected to the pressurized reaction treatment to obtain the zinc oxide nanocrystal includes:
adding the precipitant agent to the reactant-containing solution to obtain a white precipitate, and then dissolving the white precipitate in a third solvent to obtain a colloidal solution of a metal-doped zinc oxide nanocrystal.

The function of the precipitating agent is to obtain a precipitate containing the metal-doped zinc oxide nanocrystal. It may be understood that in order to remove impurities, in some embodiments, after the white precipitate is obtained, the step of washing the white precipitate is further included.

In some embodiments, a volume ratio of the reactant-containing solution to the precipitating agent ranges from 2:1 to 6:1. Within this ratio range, it is more favorable to obtain the precipitate. It may be understood that the volume ratio of the reactant-containing solution to the precipitating agent may be any value in the range of (2-6):1, such as (2-3):1, (3-4):1, (4-5):1, (5-6):1, and the like, or other unlisted values in the range of (2-6):1.

In some embodiments, the zinc salt is selected from, but not limited to, one or more of zinc acetate, zinc nitrate, zinc sulfate, and zinc chloride.

The doped metal salt may be selected from, but not limited to, one or more of a magnesium salt, an aluminum salt, a cadmium salt, a lithium salt and a gallium salt. The magnesium salt may be selected from, but not limited to, one or more of magnesium acetate, magnesium nitrate, magnesium sulfate, and magnesium chloride. The lithium salt may be selected from, but not limited to, one or more of lithium acetate, lithium nitrate, lithium sulfate, and lithium chloride. The gallium salt may be selected from, but not limited to, one or more of gallium acetate, gallium nitrate, gallium sulfate, and gallium chloride. The aluminum salt may be selected from, but not limited to, one or more of aluminum acetate, aluminum nitrate, aluminum sulfate, and aluminum chloride. The cadmium salt may be selected from, but not limited to, one or more of cadmium acetate, cadmium nitrate, cadmium sulfate, and cadmium chloride.

The doped metal element in the metal-doped zinc oxide nanocrystal is selected from one or more of magnesium, aluminum, cadmium, lithium, and gallium. It may be understood that the metal element in the doped metal salt corresponds to the metal element in the doped metal zinc oxide nanocrystal, for example, when a metal salt is selected from a magnesium salt, the zinc oxide nanocrystal is a magnesium-doped zinc oxide nanocrystal, and when the metal salt is selected from an aluminum salt, the zinc oxide nanocrystal is an aluminum-doped zinc oxide nanocrystal.

The alkali may be selected from, but is not limited to, one or more of potassium hydroxide, sodium hydroxide, lithium hydroxide, TMAH, aqueous ammonia, ethanolamine, and ethylenediamine.

The first solvent, the second solvent, and the third solvent may be solvents having a high polarity. For example, the first solvent, the second solvent, and the third solvent may each be independently selected from, but not limited to, one or more of water, methanol, ethanol, propanol, butanol, ethylene glycol, 2-Methoxyethanol, and dimethyl sulfoxide.

The precipitating agent may be a less polar solvent. The less polar solvent may be selected from, but is not limited to, one or more of ethyl acetate, acetone, n-hexane, and n-heptane.

An embodiment of the present disclosure further provides a zinc oxide nanocrystal obtained by the method as described above.

In some embodiments, an average particle size of the zinc oxide nanocrystal ranges from 3 to 20 nm.

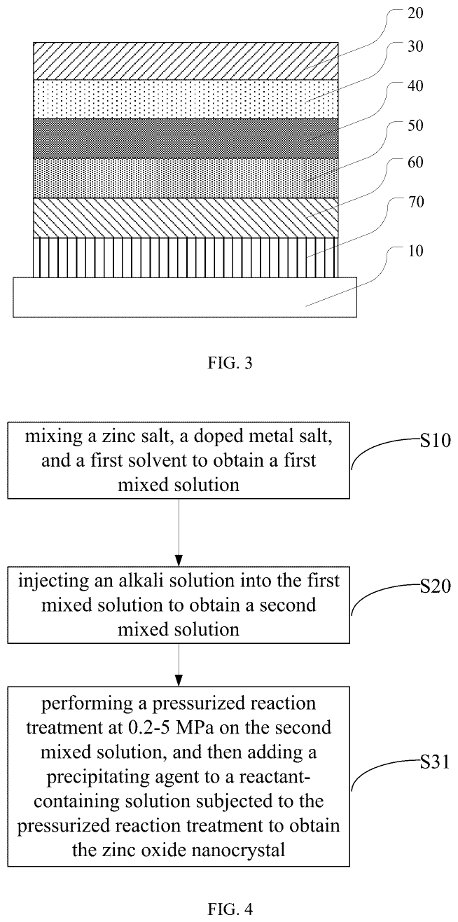

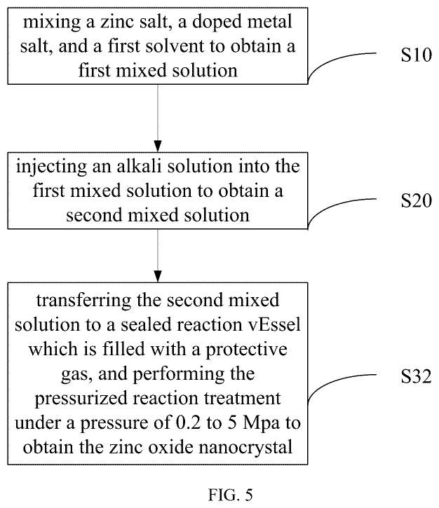

The present disclosure further provides a light-emitting device, as shown in FIGS. 2 and 3, including a cathode 70, an anode 20 disposed to the cathode 70, a light-emitting layer 50 disposed between the cathode 70 and the anode 20, and an electron transport layer 60 disposed between the cathode 70 and the light-emitting layer 50, wherein a material of the electron transport layer 60 is the zinc oxide nanocrystal prepared by the method according to the first aspect or the zinc oxide nanocrystal according to the second aspect.

In some embodiments, the light-emitting device further includes a hole injection layer 30 and a hole transport layer 40, wherein the hole injection layer 30 and the hole transport layer 40 are disposed between the light-emitting layer 50 and the anode 20, the hole injection layer 30 is disposed close to the anode 20, the hole transport layer 40 is disposed close to the light-emitting layer 50.

In some embodiments, the light emitting device is a quantum dot light emitting diode (QLED).

The light-emitting device according to an embodiment of the present disclosure may have an upright structure or an inverted structure. The side of the cathode 70 or the anode 20 remote from the light-emitting layer 50 further includes a substrate 10. In the light-emitting device having the upright structure, the anode 20 is disposed on the substrate 10, and in the light-emitting device having the inverted structure, the cathode 70 is disposed on the substrate 10. In some embodiments, the light-emitting device further includes the hole injection layer 30 and the hole transport layer 40, wherein the hole injection layer 30 and the hole transport layer 40 are disposed between the light-emitting layer 50 and the anode 20, the hole injection layer 30 is disposed close to the anode 20, the hole transport layer 40 is disposed close to the light-emitting layer 50. For example:

FIG. 2 shows a schematic diagram of an upright light-emitting device provided by an embodiment of the present disclosure. As shown in FIG. 2, the upright light-emitting device includes the substrate 10, the anode 20 provided on the surface of the substrate 10, the hole injection layer 30 provided on the surface of the anode 20, the hole transport layer 40 provided on the surface of the hole injection layer 30, the light-emitting layer 50 provided on the surface of the hole transport layer 40, the electron transport layer 60 provided on the surface of the light-emitting layer 50, and the cathode 70 provided on the surface of the electron transport layer 60. Wherein, the material of the electron transport layer 60 is selected from the zinc oxide nanocrystal prepared by the method described in the above embodiments.

FIG. 3 shows a schematic diagram of an inverted light-emitting device provided by an embodiment of the present disclosure. As shown in FIG. 3, the inverted light-emitting device includes the substrate 10, the cathode 70 provided on the surface of the substrate 10, the electron transport layer 60 provided on the surface of the cathode 70, the light-emitting layer 50 provided on the surface of the electron transport layer 60, the hole transport layer 40 provided on the surface of the light-emitting layer 50, the hole injection layer 30 provided on the surface of the hole transport layer 40, and the anode 20, wherein the material of the electron transport layer 60 is selected from zinc oxide nanocrystal prepared by the method described in the above embodiments.

The light-emitting layer 50 is adjacent to the electron transport layer 60, and an interface where the light-emitting layer 50 and the electron transport layer 60 are in contact with each other is formed, whether the light-emitting device as described above has the upright structure or the inverted structure. The defects on the surface of zinc oxide nanocrystals will quench the excitons at the interface, which will affect the luminescence performance of the device. In an embodiment of the present disclosure, by preparing zinc oxide nanocrystals under a high pressure state, the defects on the surface of zinc oxide nanocrystals are reduced, thereby improving the quenching effect of the light-emitting layer 50 and improving the light-emitting efficiency of the device.

In some embodiments, each of functional layers may be made of the following material. For example:

The substrate 10 may be a rigid substrate or a flexible substrate. Specific materials may include one or more of glass, silicon wafers, polycarbonate, poly(methyl methacrylate), polyethylene glycol terephthalate, polyethylene naphthalate, polyamide, and polyether.

The anode 20 is selected from, but not limited to, one or more of indium tin oxide, fluorine-doped tin oxide, indium zinc oxide, graphene, and carbon nanotube.

The light-emitting layer 50 is a quantum dot light-emitting layer, and the quantum dot light-emitting layer is a red quantum dot light-emitting layer, a green quantum dot light-emitting layer, a blue quantum dot light-emitting layer or a multi-component mixed quantum dot light-emitting layer; a material of the quantum dot light-emitting layer includes at least one of nanocrystals of a Group II-VI semiconductor, nanocrystals of a Group III-V semiconductor, a Group II-V compound, a Group III-VI compound, a Group IV-VI compound, a Group I-III-VI compound, a Group II-IV-VI compound, and a Group IV elemental substance.

The cathode 70 is selected from, but not limited to, one or more of Al, Ca, Ba, and Ag.

A material of the hole injection layer 30 is selected from, but not limited to, one or more of PEDOT:PSS, nickel oxide, molybdenum oxide, tungsten oxide, vanadium oxide, molybdenum sulfide, tungsten sulfide, and copper oxide.

A material of the hole transport layer 40 is selected from, but not limited to, one or more of PVK (Poly(N-vinylcarbazole)), Poly-TPD (poly-(N,N′-bis(3-methylphenyl)-N,N′-diphenyl-1,1′-biphenyl-4,4′-diamine)), CBP (4,4′-bis(9-carbazole) biphenyl), TCTA (4,4′,4′-tris (carbazol-9-yl)triphenylamine), and TFB (poly[(9,9-di-octylfluorenyl-2,7-diyl)-alt-(4,4′-(N-(4-N-butyl)phenyl)-diphenylamine)]).

Hereinafter, the present disclosure will be described in detail with reference to Examples.

### Example 1

The present embodiment provides a method for preparing a zinc oxide nanocrystal, a method for preparing a light-emitting device, and a light-emitting device.

The method for preparing the zinc oxide nanocrystals includes: injecting a solution formed by dissolving tetramethylammonium hydroxide in ethanol into a reaction apparatus containing a solution formed by dispersing zinc acetate and 5% magnesium acetate in dimethyl sulfoxide solvent at one time, and continuously stirring; using argon gas to inflate and pressurize the reaction apparatus to 0.8 MPa, and react for 1 h to obtain a zinc oxide nanocrystal doped with magnesium; the zinc oxide nanocrystal were washed twice with ethyl acetate, and then dispersed in ethanol at a ratio of 40 mg/mL.

The method of preparing the light-emitting device includes: spin-coating PEDOT:PSS material on ITO (as an anode) to form a hole injection layer, and then annealing at 100° C. for 15 minutes; then, forming a hole transport layer of TFB on the hole injection layer, and annealing at 100° C. for 15 minutes; forming a light-emitting layer of CdZnSe/CdZnS/ZnS which are green-red quantum dots on the hole transport layer; preparing an ZnO-ethanol solution containing 5% magnesium on the light-emitting layer, and annealing on a hot plate at 90° C.; finally, evaporating Ag to form an electrode layer (as a cathode), and then encapsulating to obtain a light emitting device.

### Example 2

The present embodiment provides a method for preparing a zinc oxide nanocrystal, a method for preparing a light-emitting device, and a light-emitting device.

The method for preparing the zinc oxide nanocrystals includes: injecting a solution formed by dissolving tetramethylammonium hydroxide in 2-Methoxyethanol into a reaction apparatus containing a solution formed by dispersing zinc acetate and 10% magnesium acetate in dimethyl sulfoxide solvent at one time, and continuously stirring; using argon gas to inflate and pressurize the reaction apparatus to 4 MPa, and react for 30 min to obtain a zinc oxide nanocrystal doped with magnesium; the zinc oxide nanocrystal were washed twice with ethyl acetate, and then dispersed in ethanol at a ratio of 40 mg/mL.

The method of preparing the light-emitting device includes: spin-coating PEDOT:PSS material on an anode of ITO to form a hole injection layer, and then annealing at 100° C. for 15 minutes; then, forming a hole transport layer of TFB on the hole injection layer, and annealing at 100° C. for 15 minutes; forming a light-emitting layer of CdZnSe/ZnSe/ZnS which are green quantum dots on the hole transport layer; preparing an ZnO-ethanol solution containing 10% magnesium on the light-emitting layer, and annealing on a hot plate at 90° C.; finally, evaporating Ag to form an electrode layer (as a cathode), and then encapsulating to obtain a light emitting device.

### Example 3

The present embodiment provides a method for preparing a zinc oxide nanocrystal, a method for preparing a light-emitting device, and a light-emitting device.

The method for preparing the zinc oxide nanocrystals includes: injecting a solution formed by dissolving lithium hydroxide in butanol into a reaction apparatus containing a solution formed by dispersing zinc acetate and 15% cadmium acetate in dimethyl sulfoxide solvent at one time, and continuously stirring; using argon gas to inflate and pressurize the reaction apparatus to 1.5 MPa, and react for 30 min to obtain a zinc oxide nanocrystal doped with cadmium; the zinc oxide nanocrystal doped with cadmium were washed twice with ethyl acetate, and then dispersed in ethanol at a ratio of 40 mg/mL.

The method of preparing the light-emitting device includes: spin-coating PEDOT:PSS material on an anode of ITO to form a hole injection layer, and then annealing at 100° C. for 15 minutes; then, forming a hole transport layer of TFB on the hole injection layer, and annealing at 100° C. for 15 minutes; forming a light-emitting layer of CdZnS/ZnS which are blue quantum dots on the hole transport layer; preparing an ZnO-ethanol solution containing 15% cadmium on the light-emitting layer, and annealing on a hot plate at 90° C.; finally, evaporating Ag to form an electrode layer (as a cathode), and then encapsulating to obtain a light emitting device.

### Comparative Example 1

The difference between Comparative Example 1 and Example 1 is that no pressure was applied to the reaction apparatus.

### Comparative Example 2

The difference between Comparative Example 2 and Example 2 is that no pressure was applied to the reaction apparatus.

### Comparative Example 3

The difference between Comparative Example 3 and Example 3 is that no pressure was applied to the reaction apparatus.

### Comparative Example 4

The difference between Comparative Example 4 and Example 1 is that a pressure applied to the reaction apparatus was 0.1 MPa.

### Comparative Example 5

The difference between Comparative Example 5 and Example 1 is that a pressure applied to the reaction apparatus was 6 MPa.

### Validation Example

The zinc oxide nanocrystals doped with metal elements prepared in Examples and Comparative Examples were characterized by ICP-AES, and the photoelectric properties and lifetime of the light-emitting devices were tested. Among them, a test of lifetime of the device adopts the 128-channel lifetime test system customized by Guangzhou New Vision Company. The system is designed to use constant voltage and constant current power supply to drive devices to test the change of voltage or current; using a photodiode detector and a test system to test the brightness (photocurrent) change of devices; the luminance (photocurrent) of the device was tested and calibrated using a luminance meter. The test results are shown in Tables 1 and 2. Table 1 shows the feedstock dosage of doped elements, ICP-AES content test and conversion rate calculation results in zinc oxide nanocrystals doped with metal elements; Table 2 shows test data for devices prepared in Examples and Comparative Examples.

TABLE 1

| | | The molar | |
|---|---|---|---|
| | Feed molar | proportion of | |
| | ratio of | doped element X | |
| | doped | in zinc oxide | |
| | element X | nanocrystals in | Conversion |
| | (X:Zn) | ICP-AES test | of X |
| Example 1 | Mg, 5% | 4.95% | 99.6% |
| Example 2 | Mg, 10% | 9.9% | 99% |
| Example 3 | Cd, 15% | 14.9% | 99.3% |
| Comparative Example 1 | Mg, 5% | 4.6% | 92% |
| Comparative Example 2 | Mg, 10% | 7.5% | 75% |
| Comparative Example 3 | Cd, 15% | 8.7% | 58% |
| Comparative Example 4 | Mg, 5% | 4.66% | 93.2% |
| Comparative Example 5 | Mg, 5% | 4.3% | 86% |

TABLE 2

| | EL | FWHM | EQE | T95@1000nit |
|---|---|---|---|---|
| | (nm) | (nm) | (%) | (h) |
| Example 1 | 630 | 22 | 17 | 3800 |
| Example 2 | 630 | 22 | 19 | 5500 |
| Example 3 | 470 | 21 | 15 | 160 |
| Comparative Example 1 | 630 | 22 | 8 | 900 |
| Comparative Example 2 | 630 | 22 | 10 | 2200 |
| Comparative Example 3 | 470 | 21 | 6 | 20 |
| Comparative Example 4 | 630 | 22 | 9 | 1000 |
| Comparative Example 5 | 630 | 22 | 8.5 | 950 |

Comparing Examples 1 to 3 with Comparative Examples 1 to 3, it can be seen that at the same feedstock dosage, the feedstock conversion rate of zinc oxide nanocrystals doped with metal elements synthesized under high pressure is significantly higher than that of zinc oxide nanocrystals doped with metal elements synthesized under normal pressure; furthermore, the external quantum efficiency and lifetime of the light-emitting device corresponding to the zinc oxide nanocrystals doped with metal elements synthesized under high pressure are also significantly higher than those of the light-emitting device corresponding to the zinc oxide nanocrystals doped with metal elements synthesized under normal pressure. For example, in Example 1, zinc oxide nanocrystals doped with 5% magnesium were synthesized under a pressure of 0.8 MPa, and the ratio of the amount of magnesium charged to the molar amount of zinc ions was 5%. Through ICP-AES characterization, it was found that the magnesium ion content was 4.95%, and the feedstock conversion rate reached 99.6%. In Comparative Example 1, the feedstock conversion rate was only 92% under the same feedstock dosage and normal pressure conditions. In addition, by testing the difference in conductivity between the sample of Examples and the sample of Comparative Examples by single electron device, it is found that the conductivity of the high magnesium content sample is significantly lower than that of the low magnesium content sample, which is consistent with the theoretically calculated conclusion that the band gap width of the high magnesium content is wider. Using these two kinds of doped zinc oxide nanocrystals as electron transport layers to prepare red light-emitting devices. The external quantum efficiency of the light-emitting device provided in Example 1 reached 17%, and the T95 @ 1000 nit was 3800 hours; the light-emitting device provided in Comparative Example 1 had high electron injection performance due to low magnesium doping, resulting in serious carrier imbalance problem of the device. The external quantum efficiency of the light-emitting device provided in Comparative Example 1 was 8%, and the lifetime T95 @ 1000 nit was only 900 hours. The above indicates that the light-emitting device provided in Example 1 exhibits better optoelectronic properties.

Comparing Examples 1 to 3 with Comparative Examples 4 to 5, it can be seen that at the same feedstock dosage, the feedstock conversion rate of zinc oxide nanocrystals doped with metal elements synthesized in a pressure range of 0.2 to 5 MPa is significantly higher than that of zinc oxide nanocrystals doped with metal elements synthesized outside the pressure range. Moreover, the external quantum efficiency and lifetime of the light-emitting device corresponding to the range of 0.2 to 5 MPa are also significantly higher than the external quantum efficiency and lifetime of the light-emitting device corresponding to the pressure outside the pressure range. For example, in Example 1, zinc oxide nanocrystals doped with 5% magnesium were synthesized at a pressure of 0.8 Mpa, which achieved a feedstock conversion rate of 99.6%. However, in Comparative Example 4, the feedstock conversion rate was only 93.2% under the condition of 0.1 Mpa and the same feedstock dosage. Red light-emitting devices were fabricated using these two doped zinc oxide nanocrystals as electron transport layers. Example 1 provided a light-emitting device with an external quantum efficiency of 17% and a T95 @ 1000 nit of 3800 hours, whereas Comparative Example 4 provided a light-emitting device with an external quantum efficiency of 9% and a lifetime of T95 @ 1000 nit of only 1000 hours.

The above embodiments of the present disclosure provide a zinc oxide nanocrystal and a preparation method therefor, and a light emitting device, and describe them in detail. Specific examples are used to describe the principles and implementations of the present disclosure. The description of the above embodiments is merely intended to help understand the technical solutions and the core idea of the present disclosure. It is to be understood by those of ordinary skill in the art that modifications may still be made to the technical solutions described in the foregoing embodiments, or equivalent substitutions may be made to some of the technical features therein. These modifications or substitutions do not depart the essence of the corresponding technical solutions from the scope of the embodiments of the present disclosure.

What is claimed is:

1. A method for preparing a zinc oxide nanocrystal, comprising:
mixing a zinc salt, a doped metal salt, and a first solvent to obtain a first mixed solution;
injecting an alkali solution into the first mixed solution to obtain a second mixed solution; and
performing a pressurized reaction treatment at 0.2-5 MPa on the second mixed solution to obtain the zinc oxide nanocrystal.

2. The method according to claim 1, wherein after the pressurized reaction treatment, the method further comprises:
adding a precipitating agent to a reactant-containing solution subjected to the pressurized reaction treatment to obtain the zinc oxide nanocrystal, wherein the precipitating agent is selected from one or more of ethyl acetate, acetone, n-hexane, and n-heptane.

3. The method according to claim 2, wherein a volume ratio of the reactant-containing solution to the precipitating agent ranges from 2:1 to 6:1.

4. The method according to any one of claims 1 to 3, wherein the step of performing a pressurized reaction treatment at 0.2-5 MPa on the second mixed solution to obtain the zinc oxide nanocrystal comprises:
transferring the second mixed solution to a sealed reaction vessel which is filled with a protective gas, and performing the pressurized reaction treatment under a pressure of 0.2 to 5 MPa.

5. The method according to claim 4, wherein the protective gas is selected from one or more of nitrogen, argon, carbon dioxide, and oxygen.

6. The method according to any one of claims 1 to 5, wherein a temperature of the pressurized reaction treatment ranges from 0° C. to 50° C., and a reaction time ranges from 30 minutes to 4 hours.

7. The method according to any one of claims 1 to 6, wherein a molar amount of hydroxide ions in the alkali solution is A, a sum of a molar amount of zinc ions in the zinc salt and a molar amount of metal ions in the doped metal salt is B, and a ratio of A to B ranges from 0.5:1 to 1.5:1.

8. The method according to any one of claims 1 to 7, wherein the zinc salt is selected from one or more of zinc acetate, zinc nitrate, zinc sulfate, and zinc chloride.

9. The method according to any one of claims 1 to 8, wherein the doped metal salt is selected from one or more of a magnesium salt, an aluminum salt, a cadmium salt, a lithium salt, and a gallium salt; wherein the magnesium salt is selected from one or more of magnesium acetate, magnesium nitrate, magnesium sulfate, and magnesium chloride, the lithium salt is selected from one or more of lithium acetate, lithium nitrate, lithium sulfate, and lithium chloride, the gallium salt is selected from one or more of gallium acetate, gallium nitrate, gallium sulfate, and gallium chloride, the aluminum salt is selected from one or more of aluminum acetate, aluminum nitrate, aluminum sulfate, and aluminum chloride, and the cadmium salt is selected from one or more of cadmium acetate, cadmium nitrate, cadmium sulfate, and cadmium chloride.

10. The method according to any one of claims 1 to 9, wherein an alkali in the alkali solution is selected from one or more of potassium hydroxide, sodium hydroxide, lithium hydroxide, TMAH, ethanolamine, and ethylenediamine.

11. The method according to any one of claims 1 to 10, wherein the first solvent, a second solvent for dissolving the alkali solution, and a third solvent for dissolving a metal-doped zinc oxide nanocrystal are independently selected from one or more of water, methanol, ethanol, propanol, butanol, ethylene glycol, 2-Methoxyethanol, and dimethyl sulfoxide.

12. The method according to any one of claims 1 to 11, wherein a doped metal element in the zinc oxide nanocrystal is selected from one or more of magnesium, aluminum, cadmium, lithium, and gallium.

13. The method according to any one of claims 1 to 12, wherein the zinc salt is zinc acetate;
the doped metal salt is cadmium acetate or magnesium acetate;
the alkali in the alkali solution is TMAH or lithium hydroxide;
the first solvent is dimethyl sulfoxide.

14. The method according to any one of claims 1 to 13, wherein the pressure ranges from 0.8 MPa to 4 MPa.

15. The method according to any one of claims 1 to 14, wherein the zinc salt is zinc acetate, the doped metal salt is magnesium acetate, the alkali in the alkali solution is TMAH, the first solvent is dimethyl sulfoxide and the pressure is 4 MPa.

16. A zinc oxide nanocrystal, wherein the zinc oxide nanocrystal is obtained by the method according to any one of claims 1 to 15.

17. The zinc oxide nanocrystal according to claim 16, wherein an average particle size of the zinc oxide nanocrystal ranges from 3 to 20 nm.

18. A light-emitting device, comprising:
a cathode, an anode, a light-emitting layer disposed between the cathode and the anode, and an electron transport layer disposed between the cathode and the light-emitting layer, wherein a material of the electron transport layer is a zinc oxide nanocrystal prepared by the method according to any one of claims 1 to 15, or a zinc oxide nanocrystal according to claim 16 or 17.

19. The light-emitting device according to claim 18, wherein the anode is selected from one or more of indium tin oxide, fluorine-doped tin oxide, indium zinc oxide, graphene, and carbon nanotube; and/or
the light-emitting layer is a quantum dot light-emitting layer, and the quantum dot light-emitting layer is a red quantum dot light-emitting layer, a green quantum dot light-emitting layer, a blue quantum dot light-emitting layer or a multi-component mixed quantum dot light-emitting layer; a material of the quantum dot light-emitting layer comprises at least one of nanocrystals of a Group II-VI semiconductor, nanocrystals of a Group III-V semiconductor, a Group II-V compound, a Group III-VI compound, a Group IV-VI compound, a Group I-III-VI compound, a Group II-IV-VI compound, and a Group IV elemental substance; and/or
the cathode is selected from one or more of Al, Ca, Ba, and Ag.

20. The light-emitting device according to claim 18 or 19, wherein the light-emitting device further comprises:
a hole injection layer and a hole transport layer, wherein the hole injection layer and the hole transport layer are disposed between the light-emitting layer and the anode, the hole injection layer is disposed close to the anode, the hole transport layer is disposed close to the light-emitting layer, a material of the hole injection layer is selected from one or more of PEDOT:PSS, nickel oxide, molybdenum oxide, tungsten oxide, vanadium oxide, molybdenum sulfide, tungsten sulfide, and copper oxide; and, a material of the hole transport layer is selected from one or more of PVK, Poly-TPD, CBP, TCTA, and TFB.
